(19) United States
(12) Patent Application Publication
(10) Pub. No.: US 2026/0013100 A1
(43) Pub. Date: Jan. 8, 2026

(54) SEMICONDUCTOR MEMORY DEVICE

(71) Applicant: Samsung Electronics Co., Ltd., Suwon-si (KR)

(72) Inventors: Taeyun KIM, Suwon-si (KR); Youngkwan PARK, Suwon-si (KR); Junhwa SONG, Suwon-si (KR); Jongmoo LEE, Suwon-si (KR)

(73) Assignee: Samsung Electronics Co., Ltd., Suwon-si (KR)

(21) Appl. No.: 19/005,070

(22) Filed: Dec. 30, 2024

(30) Foreign Application Priority Data
Jul. 3, 2024 (KR) 10-2024-0087763

(51) Int. Cl. H10B 12/00

(52) U.S. Cl. CPC H10B 12/30; H10B 12/03; H10B 12/05

(57) ABSTRACT

A semiconductor memory device with improved integration density and/or device performance includes a substrate; an interlayer insulating layer on the substrate; a stack structure including a plurality of cell insulating films and a plurality of cell semiconductor patterns alternately stacked on the interlayer insulating layer in a first direction perpendicular to an upper surface of the substrate; a word line on the plurality of cell semiconductor patterns, the word line extending in a second direction perpendicular to the first direction; and a bit line connected to each of the plurality of cell semiconductor patterns, the bit line extending in the first direction. A lower surface of the interlayer insulating layer includes a buried insulating pattern protruding in the first direction inside the substrate.

### CROSS-REFERENCE TO RELATED APPLICATION

This application claims priority to Korean Patent Application No. 10-2024-0087763, filed in the Korean Intellectual Property Office on Jul. 3, 2024, the entire contents of which are hereby incorporated by reference.

### BACKGROUND

The present disclosure relates to semiconductor memory devices.

A semiconductor device may refer to a core component used to control or amplify an electrical signal in an electronic device, and various types of semiconductor devices may be manufactured. For example, memory devices may be used to store and retrieve data, while non-memory devices may be used to control or amplify electrical signals. A semiconductor device is a core component of an electronic device and may be used in various fields including computers, communication equipment, consumer electronics, etc.

With the development of industry, performance and functionality requirements of electronic devices are increasing. Accordingly, high-performance characteristics of semiconductor devices are advantageous, and the degree of integration of the semiconductor devices is increasing to meet high performance characteristics. Accordingly, new transistor structures such as transistors with vertical channels and vertical stack transistors have been proposed.

### SUMMARY

Some example embodiments of the present disclosure provide a semiconductor memory device with improved electrical characteristics and/or reliability.

Some example embodiments of the present disclosure provide a semiconductor memory device that may include a substrate; an interlayer insulating layer on the substrate; a stack structure including a plurality of cell insulating films and a plurality of cell semiconductor patterns alternately stacked on the interlayer insulating layer in a first direction perpendicular to an upper surface of the substrate; a word line on the plurality of cell semiconductor patterns, the word line extending in a second direction perpendicular to the first direction; and a bit line connected to each of the plurality of cell semiconductor patterns, the bit line extending in the first direction. A lower surface of the interlayer insulating layer includes a buried insulating pattern protruding in the first direction inside the substrate.

Some example embodiments of the present disclosure further provide a semiconductor memory device that may include a substrate; an interlayer insulating layer on the substrate; a stack structure including a plurality of cell insulating films and a plurality of cell semiconductor patterns alternately stacked on the interlayer insulating layer in a first direction perpendicular to an upper surface of the substrate; a word line on the plurality of cell semiconductor patterns, the word line extending in a second direction perpendicular to the first direction; a first bit line connected to each of the plurality of cell semiconductor patterns, the first bit line extending in the first direction; and a second bit line spaced apart from the first bit line in a third direction perpendicular to the first direction. A lower surface of the interlayer insulating layer includes a buried insulating pattern protruding in the first direction inside the substrate.

Some example embodiments of the present disclosure still further provide a semiconductor memory device that may include a substrate; an interlayer insulating layer on the substrate; a stack structure including a plurality of cell insulating films and a plurality of cell semiconductor patterns alternately stacked on the interlayer insulating layer in a first direction perpendicular to an upper surface of the substrate; a word line on the plurality of cell semiconductor patterns, the word line extending in a second direction perpendicular to the first direction; a first bit line connected to each of the plurality of cell semiconductor patterns, the first bit line extending in the first direction; a second bit line spaced apart from the first bit line in a third direction perpendicular to the first direction; a capacitor structure connected to each of the plurality of cell semiconductor patterns; and a plate electrode connected to the capacitor structure, the plate electrode extending in the first and second directions. A lower surface of the interlayer insulating layer includes a plurality of buried insulating patterns protruding in the first direction inside the substrate. The plurality of buried insulating patterns include a first buried insulating pattern overlapping the bit line in the first direction, and a second buried insulating pattern overlapping the plate electrode in the first direction.

According to some example embodiments of the present disclosure, by allowing the lower surface of the plate electrode to be positioned lower than the lower surface of the stack structure through the interlayer insulating film that is disposed below the stack structure, the capacitor structure can be disposed on the lowermost portion of the stack structure, and accordingly, the degree of integration and/or performance of semiconductor memory devices can be improved.

According to some example embodiments of the present disclosure, by allowing the lower surface of the bit line to be positioned lower than the lower surface of the stack structure through the interlayer insulating film that is disposed below the stack structure, the cell semiconductor pattern can be disposed on the lowermost portion of the stack structure, and accordingly, the degree of integration and/or performance of semiconductor memory devices can be improved.

### BRIEF DESCRIPTION OF THE DRAWINGS

The above and other objects, features and advantages of the present disclosure will become more apparent to those of ordinary skill in the art in view of the following detailed description of some example embodiments thereof with reference to the accompanying drawings, in which:

FIG. 1 is an example circuit diagram illustrating a cell array of a semiconductor memory device according to some example embodiments;

FIG. 2 is a plan view provided to explain a semiconductor memory device according to some example embodiments;

FIG. 3 is a cross-sectional view taken along line A-A of FIG. 2;

FIG. 4 is an enlarged view of a region R1 of FIG. 3;

FIG. 5 is a diagram provided to explain a semiconductor memory device according to some example embodiments;

FIG. 6 is an enlarged view of a region R2 of FIG. 5;

FIG. 7 is a diagram provided to explain a semiconductor memory device according to some example embodiments;

FIG. 8 is a diagram provided to explain a semiconductor memory device according to some example embodiments;

FIG. 9 is an enlarged view of a region R3 of FIG. 8;

FIG. 10 is a diagram provided to explain a semiconductor memory device according to some example embodiments;

FIG. 11 is an enlarged view of a region R4 of FIG. 10; and

FIGS. 12, 13, 14, 15, 16, 17, 18, 19 and 20 are diagrams provided to explain a method for manufacturing a semiconductor memory device according to some example embodiments.

### DETAILED DESCRIPTION

Hereinafter, a semiconductor memory device and a method for manufacturing the same according to some example embodiments of the present disclosure will be described in detail with reference to the drawings.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

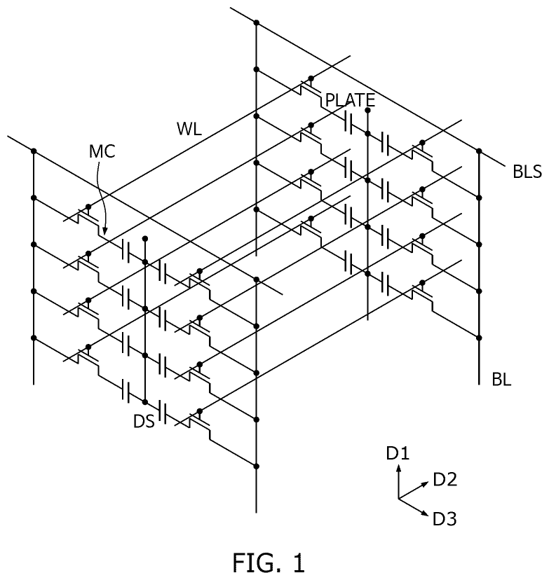

Hereinafter, in the illustrations in FIGS. 1 to 20, a first direction D1, a second direction D2, and a third direction D3 are perpendicular to one another, and the first direction D1 and the second direction D2, the second direction D2 and the third direction D3, and the first direction D1 and the third direction D3 form the same plane, respectively.

Hereinafter, a thickness of a component may refer to a thickness in the first direction D1. Further, a height of a component may refer to the height in the first direction D1. Further, a width of a component may refer to the width in the third direction D3.

FIG. 1 is an example circuit diagram illustrating a cell array of a semiconductor memory device according to some example embodiments.

Referring to FIG. 1, the semiconductor memory device according to some example embodiments may include a plurality of memory cells MC arranged along the first direction D1 and the third direction D3. Each of the memory cells MC may include memory cell transistors and data storage devices DS arranged along the third direction D3 and connected to each other.

A plurality of bit lines BL may be conductive patterns (e.g., metallic conductive lines) extending in a perpendicular direction (e.g., in the first direction D1) from the substrate. The plurality of bit lines BL may be arranged in the third direction D3. Adjacent bit lines BL may be spaced apart from each other in the third direction D3.

In some example embodiments, some of the plurality of bit lines BL may be connected to each other by a bit line strapping line BLS. For example, the bit line strapping (e.g., bundle) line BLS may connect the bit lines BL arranged along the third direction D3 of the plurality of bit lines BL to each other.

A plurality of word lines WL may be conductive patterns (e.g., metallic conductive lines) stacked on the substrate in the first direction D1. Each of the word lines WL may extend in a second direction D2. Adjacent word lines WL may be spaced apart from each other in the first direction D1.

The data storage devices DS may be commonly connected to plate electrodes PLATE extending in the first direction D1 and the second direction D2. In some example embodiments, the plate electrodes PLATE arranged along the second direction D2 may be integrally formed.

The data storage devices DS and the memory cell transistors arranged along the third direction D3 may be arranged symmetrically based on surfaces extending in the first direction D1 and the second direction D2 in which the plate electrodes PLATE are disposed.

Gates of the memory cell transistors may be connected to the word lines WL. A first source and drain of the memory cell transistor may be connected to the bit line BL. A second source and drain of the memory cell transistor may be connected to the data storage device DS. For example, the data storage device DS may be a capacitor structure. The second source and drain of the memory cell transistor may be connected to a storage electrode of the capacitor.

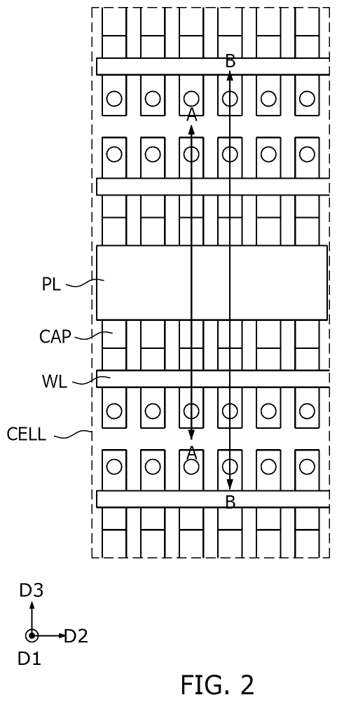

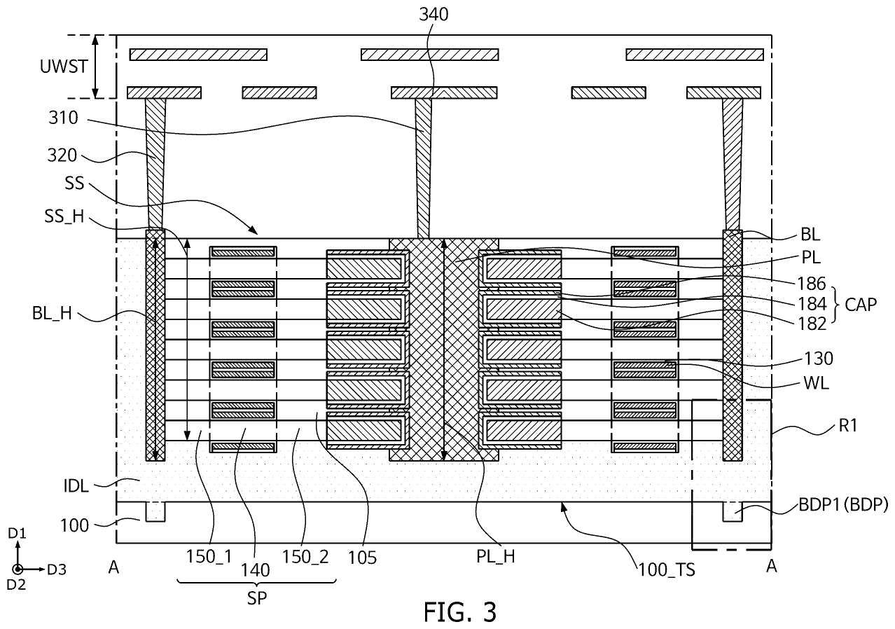

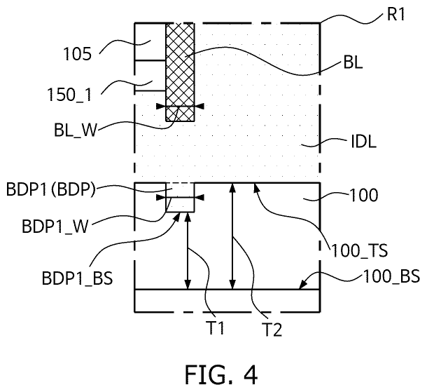

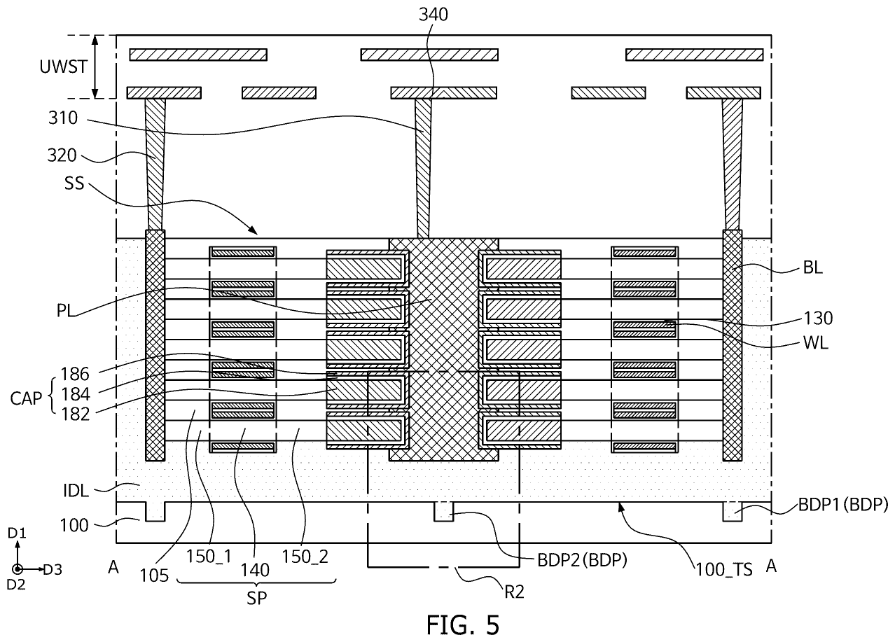

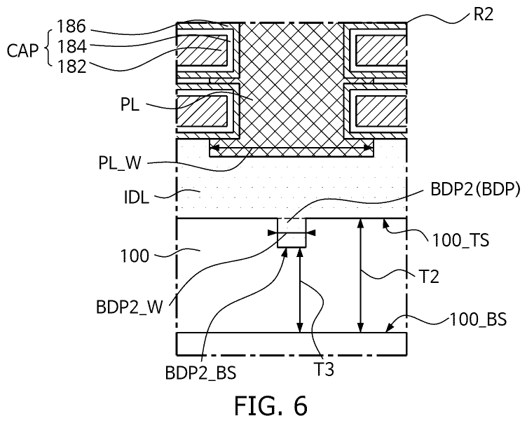

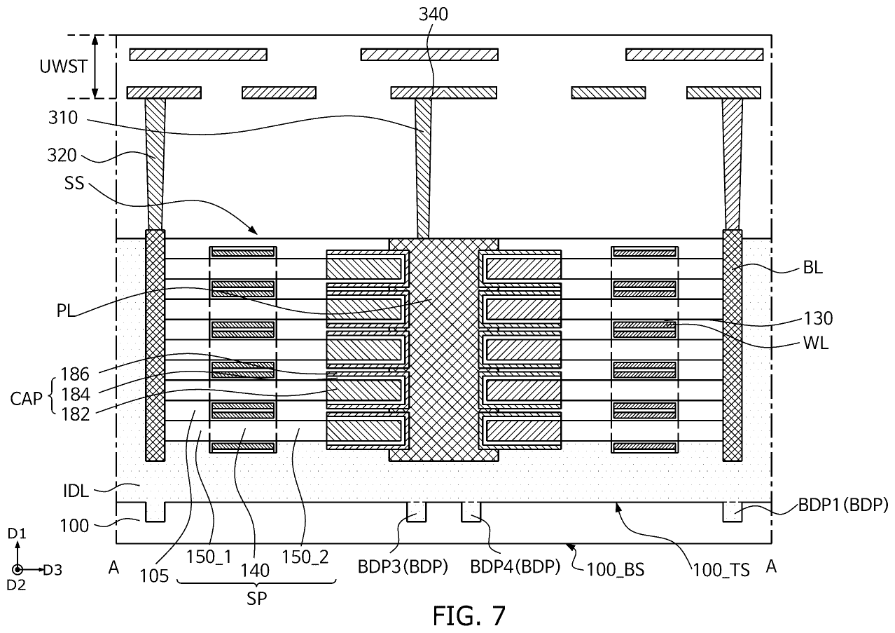

FIG. 2 is a plan view provided to explain a semiconductor memory device according to some example embodiments. FIG. 3 is a cross-sectional view taken along line A-A of FIG. 2. FIG. 4 is an enlarged view of a region R1 of FIG. 3. FIG. 5 is a diagram provided to explain a semiconductor memory device according to some example embodiments. FIG. 6 is an enlarged view of a region R2 of FIG. 5. FIG. 7 is a diagram provided to explain a semiconductor memory device according to some example embodiments. For reference, illustrations of an upper wiring structure UWST, first and second contact vias 310, 320, etc. are omitted in FIG. 2.

Referring to FIGS. 2 and 3, a substrate 100 including the cell region CELL may be provided. The substrate 100 may be a single crystal silicon substrate.

An interlayer insulating layer IDL may be disposed on the substrate 100. For example, the interlayer insulating layer IDL may be selected from the group consisting of a silicon oxide film, a silicon nitride film, a silicon oxynitride film, a carbon-containing silicon oxide film, a carbon-containing silicon nitride film, and a carbon-containing silicon oxynitride film.

A stack structure SS may be disposed on the interlayer insulating layer IDL. The stack structure SS may include a plurality of cell insulating films 105 and a plurality of cell semiconductor patterns SP alternately stacked on each other. The plurality of cell insulating films 105 and the plurality of cell semiconductor patterns SP may be alternately and repeatedly stacked on each other in the first direction D1. The first direction D1 may be a direction perpendicular to an upper surface of the substrate 100. The second direction D2 and the third direction D3 may be directions parallel to the upper surface of the substrate 100. The second direction D2 may be a direction perpendicular to the third direction D3.

The cell semiconductor pattern SP may have a line shape, a bar shape, or a pillar shape extending in the third direction D3. The cell semiconductor pattern SP may be formed through the word line WL.

For example, the cell semiconductor pattern SP may include silicon, germanium, silicon-germanium, indium gallium zinc oxide (IGZO) or indium tin zinc oxide (ITZO). For example, the cell semiconductor pattern SP may include a two-dimensional semiconductor material.

The cell semiconductor pattern SP may include a cell channel pattern 140, a first source and drain pattern 150_1, and a second source and drain pattern 150_2.

The cell channel pattern 140 may be disposed between the first source and drain pattern 150_1 and the second source and drain pattern 150_2. The cell channel pattern 140 may be disposed between the word lines WL. In some aspects, the word line WL may have a structure (e.g., a gate all around structure) that completely surrounds the cell channel pattern 140.

The first source and drain pattern 150_1 may be disposed at one end of the cell channel pattern 140. The first source and drain pattern 150_1 may be connected to the bit line BL. The second source and drain pattern 150_2 may be disposed at the other end of the cell channel pattern 140. The second source and drain pattern 150_2 may be connected to a capacitor structure CAP.

The first source and drain pattern 150_1 and the second source and drain pattern 150_2 may have a first conductivity type (e.g., an n-type). The cell channel pattern 140 may be undoped or may have a second conductivity type (e.g., a p-type) different from the first conductivity type. However, some example embodiments are not limited thereto.

Each of the plurality of word lines WL may extend in the second direction D2 parallel to the upper surface of the substrate 100. Each of the plurality of word lines WL may surround the cell channel pattern 140. Although not illustrated, the plurality of word lines WL may be disposed in a contact region. The plurality of word lines WL may have a step shape on the contact region. Each of the plurality of word lines WL may include a pad portion with an upper surface partially exposed due to the step shape. A word line contact may be disposed on the pad portion of the word line WL.

The word line WL may include a conductive material. For example, the word line WL may include at least one of doped semiconductor material (e.g., doped silicon, doped silicon-germanium, doped germanium, etc.), conductive metal nitride (e.g., titanium nitride, tantalum, etc.), metal (e.g., tungsten, titanium, tantalum, etc.), and metal-semiconductor compound (e.g., tungsten silicide, cobalt silicide, titanium silicide, etc.), but some example embodiments are not limited thereto.

The gate insulating film 130 may be disposed between the cell channel pattern 140 and the word line WL. The gate insulating film 130 may surround the cell channel pattern 140. The word line WL may be disposed on the gate insulating film 130. The gate insulating film 130 may include at least one of a high-k insulating film, a silicon oxide film, a silicon nitride film, and a silicon oxynitride film. For example, the high-k insulating film may include at least one of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobium salt.

The cell insulating film 105 may be disposed between the cell semiconductor patterns SP stacked in the first direction D1. A portion of the cell insulating film 105 may be disposed between adjacent word lines WL in the first direction D1. The cell insulating film 105 may electrically isolate the word lines WL. The other portion of the cell insulating film 105 may be disposed between adjacent capacitor structures CAP in the first direction D1.

The cell insulating film 105 may include an insulating material. For example, the cell insulating film 105 may be selected from the group consisting of a silicon oxide film, a silicon nitride film, a silicon oxynitride film, a carbon-containing silicon oxide film, a carbon-containing silicon nitride film, and a carbon-containing silicon oxynitride film. The cell insulating film 105 may include the same or substantially the same material as the interlayer insulating layer IDL.

As illustrated in FIG. 3, the capacitor structure CAP may include a first electrode 182, a first dielectric film 184, and a second electrode 186. The first electrode 182 may be disposed at one end of the cell semiconductor pattern SP. The first electrode 182 may be connected to the second source and drain pattern 150_2. The first electrode 182 may have a pillar shape extending in the third direction D3.

The first electrode 182 may include at least one of a metal material, a metal nitride film, and a metal silicide. For example, the first electrode 182 may include a high-melting point metal film such as cobalt, titanium, nickel, tungsten, molybdenum, etc. For example, the first electrode 182 may include a metal nitride film such as a titanium nitride film, a titanium silicon nitride film, a titanium aluminum nitride film, a tantalum silicon nitride film, a tantalum aluminum nitride film, a tungsten nitride film, etc.

The first dielectric film 184 may be disposed between the first electrode 182 and the second electrode 186. The first dielectric film 184 may be disposed along a profile of the first electrode 182. For example, the first dielectric film 184 may include at least one of a metal oxide such as hafnium oxide, zirconium oxide, aluminum oxide, lanthanum oxide, tantalum oxide, titanium oxide, etc., or a dielectric material having a perovskite structure such as SrTiO₃ (STO), (Ba,Sr)TiO₃ (BST), BaTiO₃, PZT, PLZT, etc.

The second electrode 186 may be disposed on the first dielectric film 184. The second electrode 186 may extend along the first dielectric film 184. The second electrode 186 may be connected to the plate electrode PL. For example, the second electrode 186 may include at least one of silicon doped with impurities, a metal material, a metal nitride film, or a metal silicide. In some example embodiments, the second electrode 186 may include the same or substantially the same material as the first electrode 182.

The plate electrode PL may extend in the first direction D1 and the second direction D2. The plate electrode PL may be in contact with the second electrode 186. The plate electrode PL may be electrically connected to a plurality of second electrodes 186 disposed in the first direction D1. The plate electrode PL may include a conductive material. For example, the plate electrode PL may include any one of a doped semiconductor material, a conductive metal nitride, a metal, and a metal-semiconductor compound. The plate electrode PL may be the plate electrode PLATE described above with reference to FIG. 1.

In some example embodiments, a lower surface of the plate electrode PL may be positioned at a lower level than a lower surface of the stack structure SS. Referring to FIG. 3, a distance PL_H between an upper surface of the stack structure SS (or an upper surface of the plate electrode PL) and the lower surface of the plate electrode PL may be greater than a distance SS_H between the upper surface of the stack structure SS and the lower surface of the stack structure SS. The lower surface of the plate electrode PL may be positioned at a lower level than a lower surface of the cell semiconductor pattern disposed lowermost among the plurality of cell semiconductor patterns SP. The lower surface of the cell semiconductor pattern disposed lowermost among the plurality of cell semiconductor patterns SP may be coplanar with the lower surface of the stack structure SS. The interlayer insulating layer IDL may be in contact with the lower surface of the plate electrode PL and with at least a portion of both sides of the plate electrode PL. Since the lower surface of the plate electrode PL is positioned at a lower level than the lower surface of the stack structure SS, the capacitor structure CAP may be disposed at a lowermost portion of the stack structure SS, which may improve the degree of integration and/or performance of semiconductor memory devices.

In some example embodiments, the capacitor structure CAP may include a hollow cylindrical electrode and a second dielectric film. For example, the cylindrical electrode may be disposed at one end of the cell semiconductor pattern SP. The cylindrical electrode may be connected to the second source and drain pattern 150_2. The plate electrode PL may fill an inner space of the cylindrical electrode. The second dielectric film may be disposed between the cylindrical electrode and the plate electrode PL. The shape and structure of the capacitor structure CAP are not limited to some example embodiments described above and various shapes and structures are possible.

The description of the material of the cylindrical electrode may be the same as the first electrode 182 of FIG. 3, and a description of the material of the second dielectric film may be the same as the first dielectric film 184 of FIG. 3.

The plurality of bit lines BL may be disposed on the substrate 100. The plurality of bit lines BL may be spaced apart and aligned in the second direction D2. The bit lines BL may extend in the first direction D1. The bit lines BL may be formed through the stack structure SS. For example, the bit lines BL may be formed through the plurality of stacked cell semiconductor patterns SP. The cell semiconductor patterns SP may be connected to the bit lines BL. For example, the bit lines BL may be electrically connected to the first source and drain pattern 150_1 of the cell semiconductor pattern SP.

In some example embodiments, lower surfaces of the bit lines BL may be positioned at a lower level than the lower surface of the stack structure SS. Referring to FIG. 3, a distance BL_H between the upper surface of the stack structure SS and the lower surface of the bit line BL may be greater than a distance SS_H between the upper surface of the stack structure SS and the lower surface of the stack structure SS. The lower surface of the bit line BL may be positioned at a lower level than the lower surface of the cell semiconductor pattern disposed lowermost among the plurality of cell semiconductor patterns SP. The lower surface of the cell semiconductor pattern disposed lowermost among the plurality of cell semiconductor patterns SP may be coplanar with the lower surface of the stack structure SS. The interlayer insulating layer IDL may be in contact with the lower surface of the bit line BL and at least a portion of both side sides of the bit line BL. Since the lower surface of the bit line BL is positioned at a lower level than the lower surface of the stack structure SS, the cell semiconductor pattern SP may be disposed at a lowermost portion of the stack structure SS, which may improve the degree of integration and/or performance of semiconductor memory devices.

The upper wiring structure UWST may be disposed on the stack structure SS. The upper wiring structure UWST may be disposed to be spaced apart from a plurality of cell channel patterns 140 in the first direction D1. The upper wiring structure UWST may include a conductive pattern 340. The upper wiring structure UWST may be a wiring electrically connecting the cell region CELL and the peripheral circuit region.

A first contact via 310 may be disposed between the upper wiring structure UWST and the plate electrode PL. The first contact via 310 may electrically connect the upper wiring structure UWST and the plate electrode PL. The first contact via 310 may extend in the first direction D1.

The second contact via 320 may be disposed between the upper wiring structure UWST and the bit line BL. The second contact via 320 may electrically connect the upper wiring structure UWST and the bit line BL. The second contact via 320 may extend in the first direction D1.

In some example embodiments, a lower surface of the interlayer insulating layer IDL may include a buried insulating pattern BDP that protrudes toward the inside of the substrate 100 in the first direction D1. For example, at least a portion of the lower surface of the interlayer insulating layer IDL may be formed through at least a portion of an upper surface 100_TS of the substrate 100 in the first direction D1.

In some example embodiments, the buried insulating pattern BDP may be disposed below the bit line BL. Referring to FIGS. 3 and 4, the buried insulating pattern BDP may include a first buried insulating pattern BDP1 overlapping the bit line BL in the first direction D1. The first buried insulating pattern BDP1 below the bit line BL may be formed through at least a portion of the upper surface of the substrate 100 in the first direction D1. Accordingly, a lower surface BDP1_BS of the first buried insulating pattern BDP1 may be positioned at a lower level than the upper surface 100_TS of the substrate 100. For example, referring to FIG. 4, a first distance T1 between the lower surface BDP1_BS of the first buried insulating pattern BDP1 and a lower surface 100_BS of the substrate 100 may be less than a second distance T2 between the upper surface 100_TS of the substrate 100 and the lower surface 100_BS of the substrate 100.

In some example embodiments, the width of each of the first buried insulating pattern BDP1 and the bit line BL may correspond to each other. For example, referring to FIG. 4, a width BDP1_W of the first buried insulating pattern BDP1 may be the same or substantially the same as a width BL_W of the bit line BL.

In some example embodiments, the buried insulating pattern BDP may be disposed below the plate electrode PL. Referring to FIGS. 5 and 6, the buried insulating pattern BDP may include a second buried insulating pattern BDP2 overlapping the plate electrode PL in the first direction D1. The second buried insulating pattern BDP2 below the plate electrode PL may be formed through at least a portion of the upper surface 100_TS of the substrate 100 in the first direction D1. Accordingly, a lower surface BDP2_BS of the second buried insulating pattern BDP2 may be positioned at a lower level than the upper surface 100_TS of the substrate 100. For example, referring to FIG. 6, a third distance T3 between the lower surface BDP2_BS of the second buried insulating pattern BDP2 and the lower surface 100_BS of the substrate 100 may be less than the second distance T2 between the upper surface 100_TS of the substrate 100 and the lower surface 100_BS of the substrate 100.

In some example embodiments, a width BDP2_W of the second buried insulating pattern BDP2 may correspond to the width (e.g., BL_W of FIG. 4) of the bit line BL. For example, referring to FIG. 6, the width BDP2_W of the second buried insulating pattern BDP2 may be less than a width PL_W of the plate electrode PL. The width BDP2_W of the second buried insulating pattern BDP2 may be the same or substantially the same as the width of the bit line BL.

In some example embodiments, a plurality of buried insulating patterns BDP may be formed on the substrate 100. For example, the plurality of buried insulating patterns BDP may be disposed below the plate electrode PL. Referring to FIG. 7, the buried insulating pattern BDP may include a third buried insulating pattern BDP3 and a fourth buried insulating pattern BDP4 overlapping the plate electrode PL in the first direction D1, respectively. Each of the third and fourth buried insulating patterns BDP3 and BDP4 below the plate electrode PL may be formed through at least a portion of the upper surface 100_TS of the substrate 100 in the first direction D1. Accordingly, the lower surface of each of the third and fourth buried insulating patterns BDP3 and BDP4 may be positioned at a lower level than the upper surface of the substrate 100. For example, a distance between the lower surface of each of the third and fourth buried insulating patterns BDP3 and BDP4 and the lower surface of the substrate may be less than the distance (e.g., the second distance T2 of FIG. 6) between the upper surface of the substrate and the lower surface of the substrate.

Referring to FIGS. 5 and 7, the buried insulating patterns BDP may be disposed together below the bit line BL and the plate electrode PL. For example, each of the first buried insulating pattern BDP1 and the second buried insulating pattern BDP2, which are spaced apart from each other, may be disposed together and formed toward the inside of the substrate 100. In some example embodiments, the first buried insulating pattern BDP1, the third buried insulating pattern BDP3, and the fourth buried insulating pattern BDP4, which are spaced apart from each other, may be disposed together and formed toward the inside of the substrate 100.

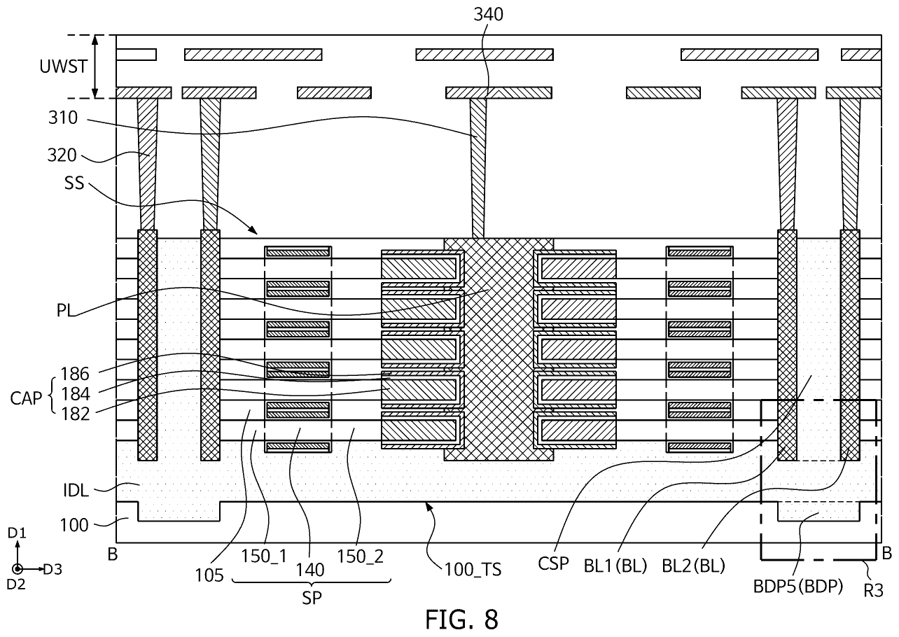

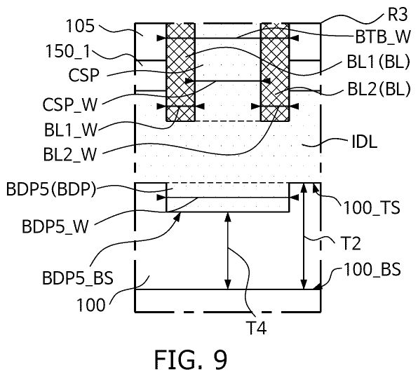

FIG. 8 is a diagram provided to explain a semiconductor memory device according to some example embodiments. FIG. 9 is an enlarged view of a region R3 of FIG. 8. For reference, FIG. 8 may correspond to a cross-sectional view taken along line B-B of FIG. 2. For convenience of description, different configurations from those described above with reference to FIGS. 2 to 7 will be mainly described.

The semiconductor memory device may further include a first bit line BL1 connected to each of the plurality of cell semiconductor patterns SP and extending in the first direction D1, and a second bit line BL2 spaced apart from the first bit line BL1 in the third direction D3 which is perpendicular to the first direction D1.

In some example embodiments, the buried insulating pattern BDP may include a fifth buried insulating pattern BDP5 overlapping the first bit line BL1 and the second bit line BL2 in the first direction D1. Referring to FIG. 9, the fifth buried insulating pattern BDP5 below the bit line BL may be formed through at least a portion of the upper surface 100_TS of the substrate 100 in the first direction D1. Accordingly, a lower surface BDP5_BS of the fifth buried insulating pattern BDP5 may be positioned at a lower level than the upper surface 100_TS of the substrate 100. For example, a fourth distance T4 between the lower surface BDP5_BS of the fifth buried insulating pattern BDP5 and the lower surface 100_BS of the substrate 100 may be less than the second distance T2 between the upper surface 100_TS of the substrate 100 and the lower surface 100_BS of the substrate 100.

Referring back to FIGS. 8 and 9, the interlayer insulating layer IDL may include an isolation insulating pattern CSP extending from at least a portion of the upper surface in the first direction D1. The isolation insulating pattern CSP may be disposed between the first bit line BL1 and the second bit line BL2. The isolation insulating pattern CSP and the fifth buried insulating pattern BDP5 may be simultaneously formed during a process of forming the stack structure SS. The remaining region of the interlayer insulating layer IDL may also be formed together.

In some example embodiments, a width BDP5_W of the fifth buried insulating pattern BDP5 may be the same or substantially the same as a distance BTB_W between an outer side of the first bit line and an outer side of the second bit line. Referring to FIG. 9, the width BDP5_W of the fifth buried insulating pattern BDP5 may be the same or substantially the same as the sum of a width BL1_W of the first bit line BL1, a width BL2_W of the second bit line BL2, and a width CSP_W of the isolation insulating pattern CSP.

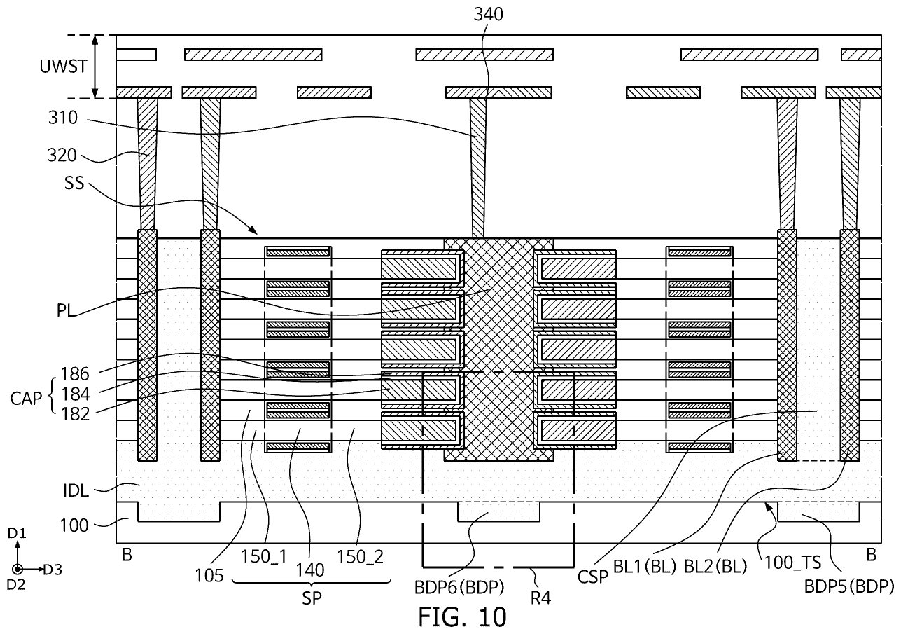

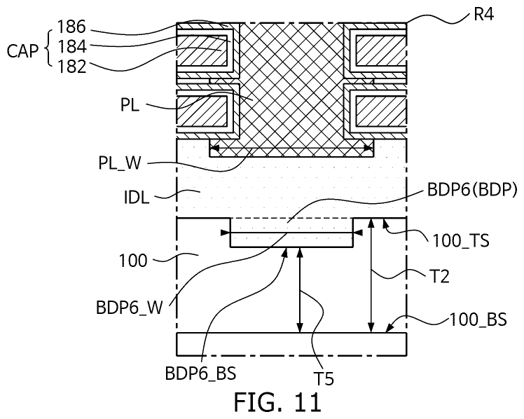

FIG. 10 is a diagram provided to explain a semiconductor memory device according to some example embodiments. FIG. 11 is an enlarged view of a region R4 of FIG. 10. For reference, FIG. 10 may correspond to a cross-sectional view taken along line B-B of FIG. 2. For convenience of description, different configurations from those described above with reference to FIGS. 2 to 9 will be mainly described.

In some example embodiments, the buried insulating pattern BDP may include a sixth buried insulating pattern BDP6 overlapping the plate electrode PL in the first direction D1. Referring to FIG. 11, the sixth buried insulating pattern BDP6 below the plate electrode PL may be formed through at least a portion of the upper surface 100_TS of the substrate 100 in the first direction D1. Accordingly, a lower surface BDP6_BS of the sixth buried insulating pattern BDP6 may be positioned at a lower level than the upper surface 100_TS of the substrate 100. For example, a fifth distance T5 between the lower surface BDP6_BS of the sixth buried insulating pattern BDP6 and the lower surface 100_BS of the substrate 100 may be less than the second distance T2 between the upper surface 100_TS of the substrate 100 and the lower surface 100_BS of the substrate 100.

In some example embodiments, the sixth buried insulating pattern BDP6 may be formed simultaneously with the fifth buried insulating pattern (e.g., BDP5 of FIG. 8). Accordingly, a width BDP6_W of the sixth buried insulating pattern BDP6 may be the same or substantially the same as the width (e.g., BDP5_W of FIG. 9) of the fifth buried insulating pattern. For example, a width of the sixth buried insulating pattern BDP6 may be the same or substantially the same as the distance (e.g., BTB_W of FIG. 9) between the outer side of the first bit line and the outer side of the second bit line. Referring to FIG. 11, the width of the sixth buried insulating pattern BDP6 may be the same or substantially the same as the sum of the width of the first bit line (e.g., BL1_W of FIG. 9), the width of the second bit line (e.g., BL2_W of FIG. 9), and the width of the isolation insulating pattern (e.g., CSP_W of FIG. 9).

Referring to FIG. 10, the buried insulating pattern BDP may be disposed together below the bit line BL and the plate electrode PL. For example, the fifth buried insulating pattern BDP5 and the sixth buried insulating pattern BDP6 may be disposed together and formed toward the inside of the substrate 100.

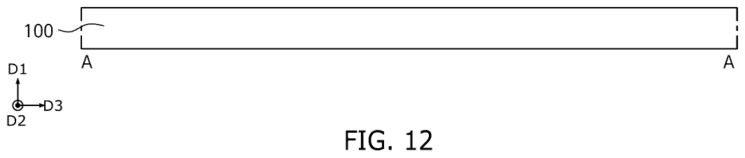

FIGS. 12 to 20 are diagrams provided to explain a method for manufacturing a semiconductor memory device according to some example embodiments. For reference, FIGS. 12 to 20 may be diagrams corresponding to a cross-sectional view taken along line A-A of FIG. 2. Hereinafter, for convenience of description, the semiconductor memory device illustrated with reference to FIG. 7 will be mainly described.

Referring to FIG. 12, the substrate 100 may be provided. The substrate 100 may be a single crystal silicon substrate.

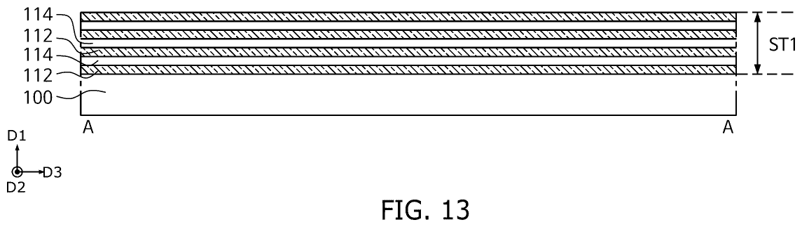

Referring to FIG. 13, a first pre-stack structure ST1 may be formed on the substrate 100. The first pre-stack structure ST1 may include a plurality of first lower semiconductor layers 112 and a plurality of second lower semiconductor layers 114 alternately stacked on each other. The plurality of first lower semiconductor layers 112 and the plurality of second lower semiconductor layers 114 may be alternately and repeatedly stacked in the first direction D1.

The first lower semiconductor layers 112 may include silicon germanium (SiGe). In some example embodiments, the first lower semiconductor layers 112 may include carbon-doped silicon-germanium (SiGe:C), boron-doped silicon-germanium (SiGe:B), carbon-doped silicon-germanium (SiGe:C), carbon and boron-doped silicon-germanium (SiGe:C:B). However, some example embodiments are not limited thereto. In some example embodiments, the first lower semiconductor layers 112 may be formed by using a selective epitaxial process.

The second lower semiconductor layers 114 may include silicon (Si). In some example embodiments, the second lower semiconductor layers 114 may be formed by using a selective epitaxial process.

Although the plurality of first lower semiconductor layers 112 and the plurality of second lower semiconductor layers 114 is illustrated as including three and four layers, respectively, some example embodiments are not limited thereto, and more or less layers may be included.

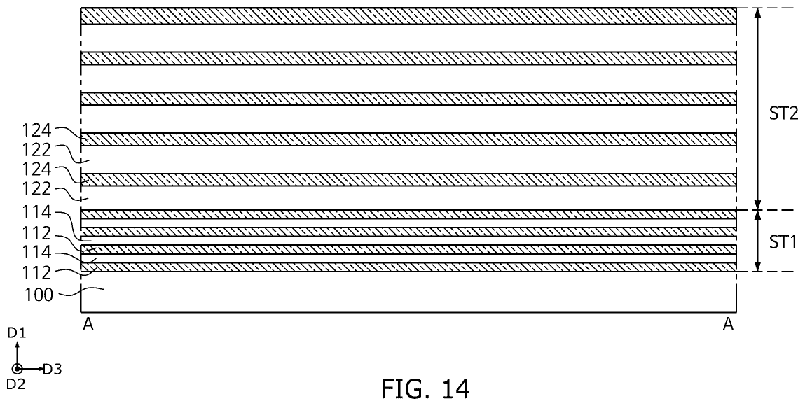

Referring to FIG. 14, a second pre-stack structure ST2 may be formed on the first pre-stack structure ST1. The second pre-stack structure ST2 may include a plurality of first upper semiconductor layers 122 and a plurality of second upper semiconductor layers 124 alternately stacked on each other. The plurality of first upper semiconductor layers 122 and the plurality of second upper semiconductor layers 124 may be alternately and repeatedly stacked in the first direction D1.

The first upper semiconductor layers 122 may include the same material as the second lower semiconductor layers 114. In some example embodiments, the first upper semiconductor layers 122 may be formed by using a selective epitaxial process.

The second upper semiconductor layers 124 may include the same material as the first lower semiconductor layers 112. In some example embodiments, the second upper semiconductor layers 124 may be formed by using a selective epitaxial process.

Although the plurality of first upper semiconductor layers 122 and the plurality of second upper semiconductor layers 124 are illustrated as including five layers, respectively, some example embodiments are not limited thereto, more or less layers may be included.

In some example embodiments, a thickness of the first upper semiconductor layer 122 may be greater than a thickness of the second lower semiconductor layer 114. The thickness of the second upper semiconductor layer 124 may be the same or substantially the same as or greater than the thickness of the first lower semiconductor layer 112.

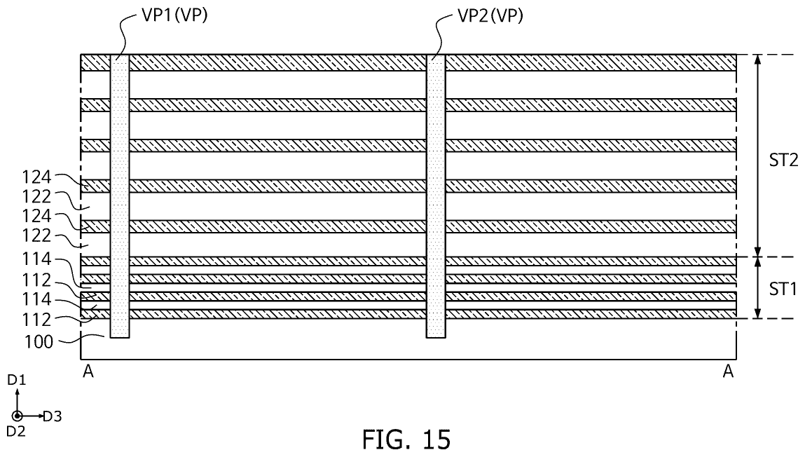

Referring to FIG. 15, a plurality of vertical pillars VP may be formed through portions of the first pre-stack structure ST1, the second pre-stack structure ST2, and the substrate 100 in the first direction D1. For example, a plurality of vertical pillar trenches may be formed by patterning portions of the first pre-stack structure ST1, the second pre-stack structure ST2, and the substrate 100 on an upper surface of the second pre-stack structure ST2. The plurality of vertical pillar trenches may be formed to be spaced apart from each other in the third direction D3. The plurality of vertical pillars VP may be formed by filling the inside of the vertical pillar trench with an insulating material.

The plurality of vertical pillars VP may be selected from the group consisting of, for example, a silicon oxide film, a silicon nitride film, a silicon oxynitride film, a carbon-containing silicon oxide film, a carbon-containing silicon nitride film, and a carbon-containing silicon oxynitride film.

The plurality of vertical pillars VP may include a first vertical pillar VP1 and a second vertical pillar VP2. The first vertical pillar VP1 and the second vertical pillar VP2 may be disposed to be spaced apart from each other in the third direction D3. The plurality of vertical pillars VP may extend from the upper surface of the second pre-stack structure ST2 to a vertical level between the upper surface and the lower surface of the substrate 100. Accordingly, an insulating pattern buried toward the inside of the substrate 100 may be formed.

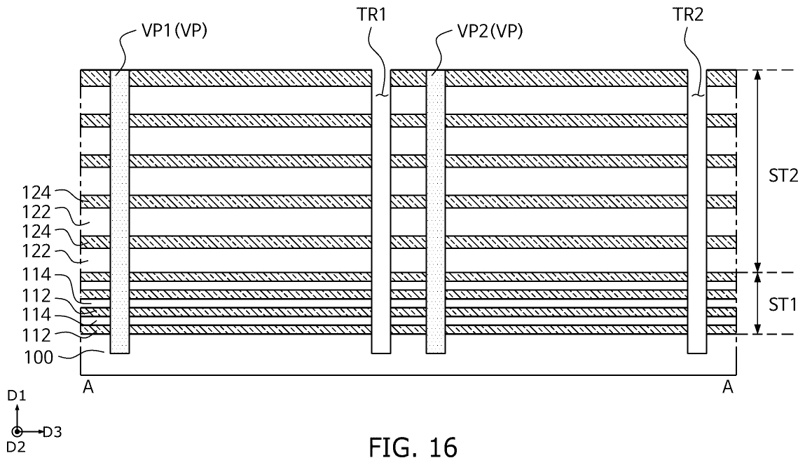

Referring to FIG. 16, a plurality of trenches TR1 and TR2 may be formed through portions of the first pre-stack structure ST1, the second pre-stack structure ST2, and the substrate 100 in the first direction D1. For example, each of the plurality of trenches TR1 and TR2 may be formed by patterning portions of the first pre-stack structure ST1, the second pre-stack structure ST2, and the substrate 100 on the upper surface of the second pre-stack structure ST2.

The plurality of trenches TR1 and TR2 may include a first trench TR1 and a second trench TR2. The first trench TR1 and the second trench TR2 may be formed to be spaced apart from each other in the third direction D3.

In some example embodiments, each of the plurality of trenches TR1 and TR2 may be alternately arranged with each of the plurality of vertical pillars VP. For example, the first trench TR1 may be disposed between the first vertical pillar VP1 and the second vertical pillar VP2. The second trench TR2 may be disposed in a direction opposite to the first trench TR1 with respect to the second vertical pillar VP2. The plurality of trenches TR1 and TR2 may extend from the upper surface of the second pre-stack structure ST2 to a vertical level between the upper surface and the lower surface of the substrate 100.

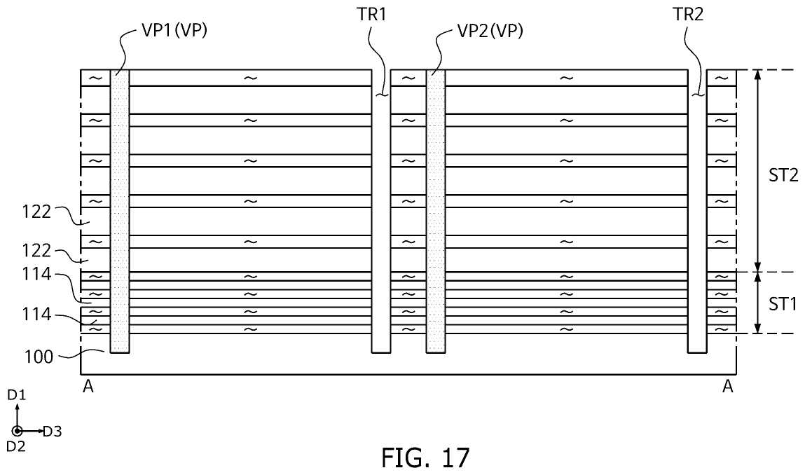

Referring to FIG. 17, the first lower semiconductor layers 112 of the first pre-stack structure ST1 and the second upper semiconductor layers 124 of the second pre-stack structure ST2 may be removed. For example, the first lower semiconductor layers 112 and the second upper semiconductor layers 124 may be selectively removed through each of the first trench TR1 and the second trench TR2. The second lower semiconductor layers 114 and the first upper semiconductor layers 122 may remain. The plurality of vertical pillars VP may support the first pre-stacked structure (ST1) and the second pre-stacked structure ST2 during the removal of the first lower semiconductor layers 112 and the second upper semiconductor layers 124.

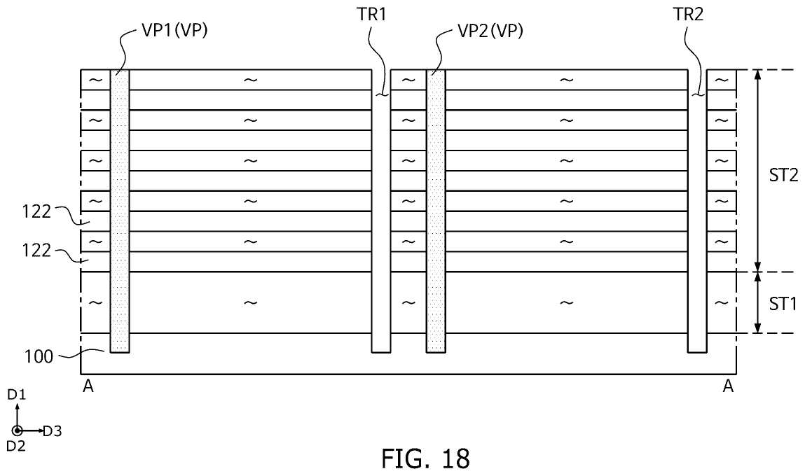

Referring to FIG. 18, the second lower semiconductor layers 114 of the first pre-stack structure ST1 may be removed. For example, the second lower semiconductor layers 114 may be removed by performing a thinning process through each of the first trench TR1 and the second trench TR2. The thickness of the first upper semiconductor layer 122 of the second pre-stack structure ST2 may be reduced.

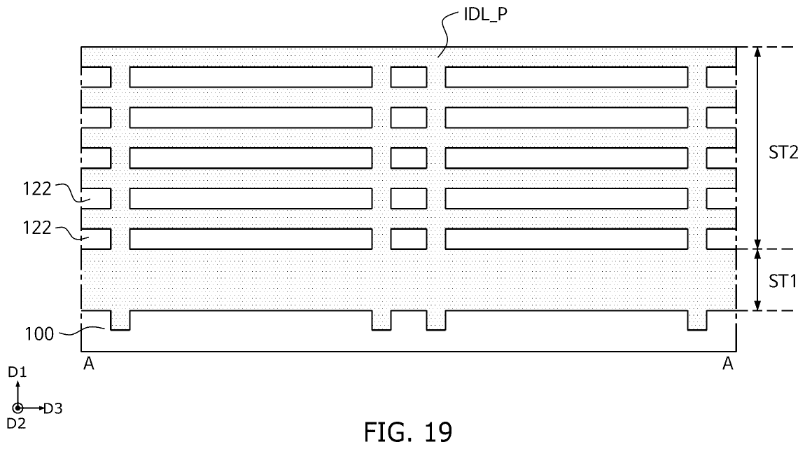

Referring to FIG. 19, a pre-interlayer insulating layer IDL_P may be formed in a space from which the first lower semiconductor layer 112, the second lower semiconductor layer 114, and the second upper semiconductor layer 124 have been removed. For example, an insulating material may fill the space from which the first lower semiconductor layer 112, the second lower semiconductor layer 114, and the second upper semiconductor layer 124 have been removed through each of the first trench TR1 and the second trench TR2. An insulating pattern buried in the substrate 100 may be formed due to the plurality of trenches TR1 and TR2 extending to the vertical level between the upper surface and the lower surface of the substrate 100. Accordingly, an insulating pattern corresponding to a height of the first pre-stack structure ST1 or having a height greater than the height of the first pre-stack structure ST1 may be formed on a lower surface of the second pre-stack structure ST2. The insulating pattern disposed between the second pre-stack structure ST2 and the substrate 100 may be used as an interlayer insulating layer (e.g., IDL of FIG. 3). The pre-interlayer insulating layer IDL_P may include the same material as the interlayer insulating layer IDL.

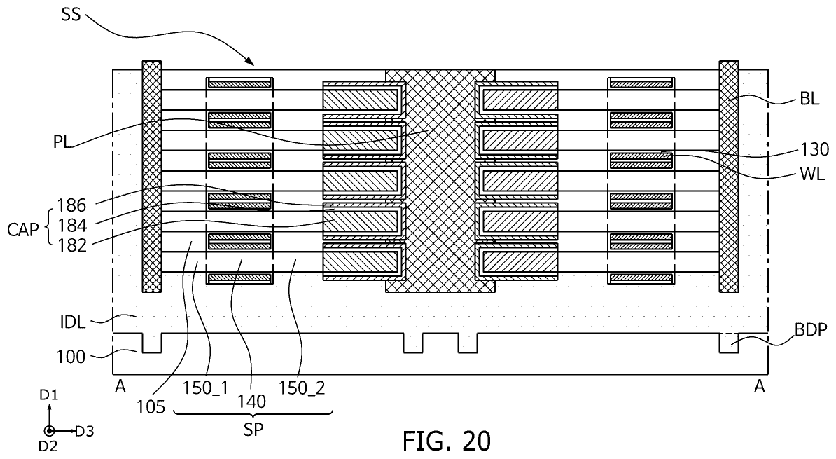

Referring to FIG. 20, the stack structure SS, the capacitor structure CAP, the plate electrode PL, etc. may be formed. For example, a portion of the first upper semiconductor layers 122 may be removed to form the cell channel pattern 140. A portion of the first upper semiconductor layers 122 and a portion of the pre-interlayer insulating layer IDL_P may be removed to form the plate electrode PL. The pre-interlayer insulating layer IDL_P interposed between the first upper semiconductor layers 122 may be the cell insulating film 105. A portion of the pre-interlayer insulating layer IDL_P may be removed from where the first vertical pillar (VP1 of FIGS. 15 to 18) and the second vertical pillar (VP2 of FIGS. 15 to 18) are formed, thus forming the bit line BL. The bit line BL and/or plate electrode PL may be formed utilizing the plurality of vertical pillars VP and the plurality of trenches TR1 and TR2 thereby reducing the need for patterning of the first pre-stacked structure ST1 and the second pre-stacked structure ST2. Description of the stack structure SS may be the same as the above description of FIG. 3.

Referring to FIG. 3, the first and second contact vias 310 and 320 and the upper wiring structure UWST may be formed above the stack structure SS.

The semiconductor device described with reference to FIGS. 3, 5, 7, 8, and 10 may be manufactured using the same or similar method as the method for manufacturing the semiconductor device described above.

Although the present disclosure has been described above by way of some example embodiments and drawings, the present disclosure is not limited thereto, and various changes and modifications can be made within the equivalent scope of the technical idea of the present disclosure and the claims to be described below by those of ordinary skill in the art.

1. A semiconductor memory device, comprising:
a substrate;
an interlayer insulating layer on the substrate;
a stack structure including a plurality of cell insulating films and a plurality of cell semiconductor patterns alternately stacked on the interlayer insulating layer in a first direction perpendicular to an upper surface of the substrate;
a word line on the plurality of cell semiconductor patterns, the word line extending in a second direction perpendicular to the first direction; and
a bit line connected to each of the plurality of cell semiconductor patterns, the bit line extending in the first direction,
wherein a lower surface of the interlayer insulating layer includes a buried insulating pattern protruding in the first direction inside the substrate.

2. The semiconductor memory device according to claim 1, wherein
a distance between an upper surface of the interlayer insulating layer and the lower surface of the interlayer insulating layer is greater than a thickness of each of the plurality of cell insulating films, and
the upper surface of the interlayer insulating layer contacts a lower surface of the stack structure.

3. The semiconductor memory device according to claim 1, wherein the buried insulating pattern comprises a first buried insulating pattern overlapping the bit line in the first direction.

4. The semiconductor memory device according to claim 3, wherein a width of the first buried insulating pattern is a same width as a width of the bit line.

5. The semiconductor memory device according to claim 1, wherein the semiconductor memory device further includes:
a capacitor structure connected to each of the plurality of cell semiconductor patterns; and
a plate electrode connected to the capacitor structure, the plate electrode extending in the first and second directions.

6. The semiconductor memory device according to claim 5, wherein the buried insulating pattern comprises a first buried insulating pattern overlapping the plate electrode in the first direction.

7. The semiconductor memory device according to claim 6, wherein a width of the first buried insulating pattern is a same width as a width of the bit line.

8. The semiconductor memory device according to claim 5, wherein
the buried insulating pattern comprises a plurality of buried insulating patterns,
the plurality of buried insulating patterns includes a first buried insulating pattern and a second buried insulating pattern overlapping the plate electrode in the first direction, and
the first buried insulating pattern and the second buried insulating pattern are spaced apart from each other in a third direction perpendicular to the first direction and the second direction.

9. The semiconductor memory device according to claim 5, wherein a lower surface of the plate electrode is at a lower level than a lower surface of the stack structure.

10. The semiconductor memory device according to claim 1, wherein a lower surface of the bit line is at a lower level than a lower surface of the stack structure.

11. The semiconductor memory device according to claim 1, wherein the interlayer insulating layer contacts a lower surface of the bit line and at least a portion of both sides of the bit line.

12. The semiconductor memory device according to claim 5, wherein the interlayer insulating layer contacts a lower surface of the plate electrode and at least a portion of both sides of the plate electrode.

13. A semiconductor memory device, comprising:
a substrate;
an interlayer insulating layer on the substrate;
a stack structure including a plurality of cell insulating films and a plurality of cell semiconductor patterns alternately stacked on the interlayer insulating layer in a first direction perpendicular to an upper surface of the substrate;
a word line on the plurality of cell semiconductor patterns, the word line extending in a second direction perpendicular to the first direction;
a first bit line connected to each of the plurality of cell semiconductor patterns, the first bit line extending in the first direction; and
a second bit line spaced apart from the first bit line in a third direction perpendicular to the first direction,
wherein a lower surface of the interlayer insulating layer includes a buried insulating pattern protruding in the first direction inside the substrate.

14. The semiconductor memory device according to claim 13, wherein the buried insulating pattern comprises a first buried insulating pattern overlapping the first bit line and the second bit line in the first direction.

15. The semiconductor memory device according to claim 14, wherein the interlayer insulating layer further includes an isolation insulating pattern extending from an upper surface of the interlayer insulating layer in the first direction and between the first bit line and the second bit line.

16. The semiconductor memory device according to claim 15, wherein a width of the first buried insulating pattern is equal to a sum of a width of the first bit line, a width of the isolation insulating pattern, and a width of the second bit line.

17. The semiconductor memory device according to claim 13, wherein the semiconductor memory device further includes:
a capacitor structure connected to each of the plurality of cell semiconductor patterns; and
a plate electrode connected to the capacitor structure, the plate electrode extending in the first and second directions.

18. The semiconductor memory device according to claim 17, wherein
the buried insulating pattern comprises a first buried insulating pattern overlapping the plate electrode in the first direction, and
a width of the first buried insulating pattern is a same width as a distance between an outer side of the first bit line and an outer side of the second bit line.

19. A semiconductor memory device, comprising:
a substrate;
an interlayer insulating layer on the substrate;
a stack structure including a plurality of cell insulating films and a plurality of cell semiconductor patterns alternately stacked on the interlayer insulating layer in a first direction perpendicular to an upper surface of the substrate;
a word line on the plurality of cell semiconductor patterns, the word line extending in a second direction perpendicular to the first direction;
a first bit line connected to each of the plurality of cell semiconductor patterns, the first bit line extending in the first direction;
a second bit line spaced apart from the first bit line in a third direction perpendicular to the first direction;
a capacitor structure connected to each of the plurality of cell semiconductor patterns; and
a plate electrode connected to the capacitor structure, the plate electrode extending in the first and second directions,
wherein a lower surface of the interlayer insulating layer includes a plurality of buried insulating patterns protruding in the first direction inside the substrate, and
wherein the plurality of buried insulating patterns include a first buried insulating pattern overlapping the first and second bit lines in the first direction, and a second buried insulating pattern overlapping the plate electrode in the first direction.

20. The semiconductor memory device according to claim 19, wherein a width of each of the first buried insulating pattern and the second buried insulating pattern is equal to or greater than a width of the first bit line.
